(19) United States
(12) Patent Application Publication
(10) Pub. No.: US 2026/0303050 A1
(43) Pub. Date: Oct. 1, 2026

(54) DIPLEXER

(71) Applicant: Murata Manufacturing Co., Ltd., Nagaokakyo-shi (JP)

(72) Inventors: Akira TANAKA, Nagaokakyo-shi (JP); Hiroto MOTOYAMA, Nagaokakyo-shi (JP)

(21) Appl. No.: 19/535,160

(22) Filed: Feb. 10, 2026

(30) Foreign Application Priority Data
Mar. 27, 2025 (JP) 2025-053199

(51) Int. Cl. H03H 7/01; H01F 27/28; H01G 4/005; H01G 4/30; H03H 7/46

(52) U.S. Cl. CPC H03H 7/0115; H01F 27/2804; H01G 4/005; H01G 4/30; H03H 7/17; H03H 7/46; H01F 2027/2809

(57) ABSTRACT

A diplexer includes a first filter defining a high-pass filter, and a second filter defining a low-pass filter adjacent to the first filter. The first filter includes a first electrode in a first dielectric layer, a second electrode defining a ground electrode in a second dielectric layer, capacitor electrodes between the first electrode and the second electrode, open vias respectively connecting the first electrode and the capacitor electrodes, and short-circuit vias connecting the first and second electrodes. At least one of the open vias is located at a position closer to a boundary surface between the first and second filters than at least one of the short-circuit vias.

### CROSS REFERENCE TO RELATED APPLICATIONS

This application claims the benefit of priority to Japanese Patent Application No. 2025-053199 filed on Mar. 27, 2025. The entire contents of this application are hereby incorporated herein by reference.

### BACKGROUND OF THE INVENTION

### 1. Field of the Invention

The present disclosure relates to diplexers.

### 2. Description of the Related Art

A diplexer including a low-pass filter and a high-pass filter is disclosed in International Publication No. WO 2023/145495. The diplexer disclosed in International Publication No. WO 2023/145495 is designed with circuits of a low-pass filter and a high-pass filter to have predetermined pass characteristics.

The diplexer as disclosed in International Publication No. WO 2023/145495 may be mounted in an electronic device, such as a mobile terminal. In that case, it is preferable that the substrate on which the diplexer is mounted is disposed closer to surrounding components for miniaturization or higher-density integration of the electronic device.

At this time, the substrate on which the diplexer is mounted may be shielded by a metal member to block electromagnetic waves from surrounding components. In this case, however, because the diplexer is proximate to the metal member, its pass characteristics may vary due to electromagnetic influence from the metal shield.

Therefore, it is preferable that the diplexer is able to reduce or prevent variations in its pass characteristics due to electromagnetic influence from the proximate metal member.

### SUMMARY OF THE INVENTION

Example embodiments of the present invention provide diplexers each able to reduce or prevent variations in its pass characteristics due to electromagnetic influence from a proximate metal shield.

A diplexer according to an example embodiment of the present invention includes multiple dielectric layers. The diplexer includes a first filter defining a high-pass filter, and a second filter defining a low-pass filter adjacent to the first filter and passing signals in a frequency band lower than a passband of the first filter. The first filter includes a first electrode in a first dielectric layer among the multiple dielectric layers, a second electrode defining a ground electrode in a second dielectric layer different from the first dielectric layer among the multiple dielectric layers, multiple capacitor electrodes between the first electrode and the second electrode, multiple open vias respectively connecting the first electrode and the multiple capacitor electrodes, and multiple short-circuit vias connecting the first electrode and the second electrode. At least one of the multiple open vias is located at a position closer to a boundary surface between the first filter and the second filter than at least one of the multiple short-circuit vias.

In a diplexer according to an example embodiments of the present invention, since at least one of the multiple open vias is located at a position closer to a boundary surface between the first filter and the second filter than at least one of the multiple short-circuit vias, variations in pass characteristics due to electromagnetic influence from a proximate metal shield are reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of a diplexer according to an example embodiment of the present invention.

FIG. 2 is a plan view of a diplexer according to an example embodiment of the present invention.

FIG. 3 is a circuit diagram of a diplexer according to an example embodiment of the present invention.

FIG. 4 is a perspective view of a diplexer according to a comparative configuration.

FIG. 5 is a plan view of the diplexer according to the comparative configuration.

FIG. 6 is a schematic diagram of a side surface of the diplexer according to the comparative configuration.

FIG. 7 is a schematic diagram of a side surface of a diplexer according to an example embodiment of the present invention.

FIG. 8 is a diagram illustrating an example of variations in the pass characteristics of each diplexer.

FIG. 9 is a perspective view of a diplexer according to Modified example 1 of an example embodiment of the present invention.

FIG. 10 is a plan view of the diplexer according to Modified example 1.

FIG. 11 is a plan view of a diplexer according to Modified example 3 of an example embodiment of the present invention.

FIG. 12 is a plan view of a diplexer according to Modified example 5 of an example embodiment of the present invention.

FIG. 13 is a perspective view of a diplexer according to Modified example 7 of an example embodiment of the present invention.

### DETAILED DESCRIPTION OF THE EXAMPLE EMBODIMENTS

Hereinafter, example embodiments of the present invention will be described in detail with reference to the drawings. The same reference numerals are assigned to the same or corresponding elements, and descriptions thereof will not be repeated.

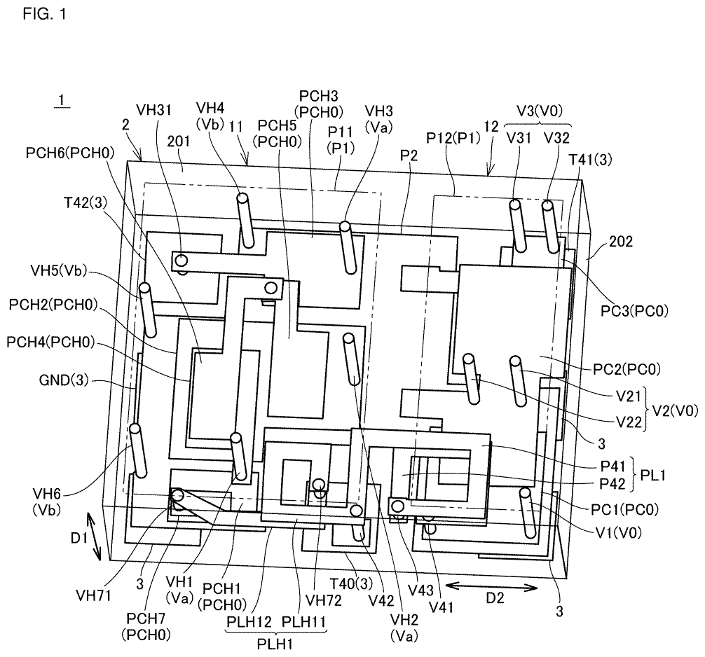

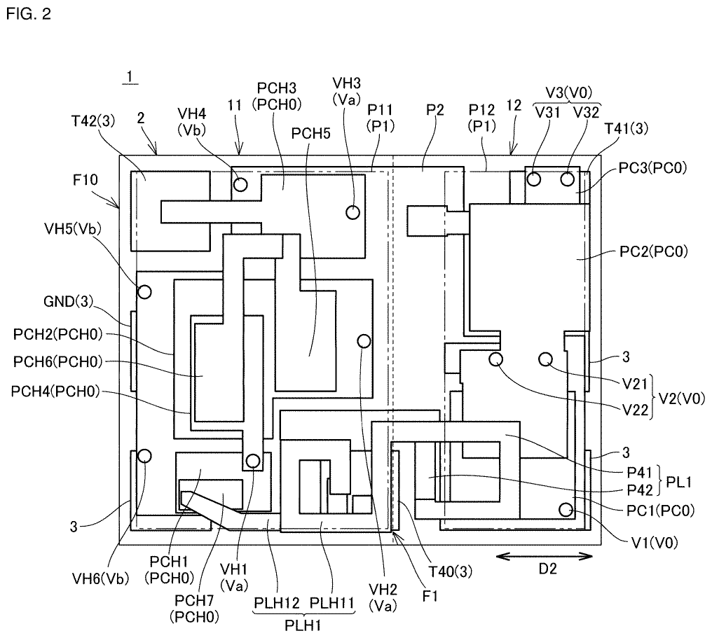

Referring to FIGS. 1 and 2, the structure of a diplexer 1 according to an example embodiment of the present invention will be described. FIG. 1 is a perspective view of the diplexer 1 according to the present example embodiment. FIG. 2 is a plan view of the diplexer 1 according to the present example embodiment. The diplexer 1 includes multiple terminals 3, multiple (two in the illustrated example) first electrodes P1, a second electrode P2, multiple capacitor electrodes PC0 and PCH0, and multiple inductor vias (later-described open vias Va, later-described short-circuit vias Vb, and vias V0 for a second filter). The diplexer 1 further includes a first filter 11 and a second filter 12.

The diplexer 1 according to the present example embodiment includes a multilayer body including multiple dielectric layers (not illustrated) that are laminated together in a laminating direction. The multilayer body 2 has a rectangular parallelepiped shape or a substantially rectangular parallelepiped shape. Each of the multiple dielectric layers of the multilayer body 2 is made of, for example, a ceramic material. Inside the multilayer body 2, inductors and capacitors are provided by multiple wiring pattern portions, multiple electrodes, and multiple vias (via conductors) provided in the respective dielectric layers. The multilayer body 2 is not limited to a rectangular parallelepiped shape or a substantially rectangular parallelepiped shape, and may have another three-dimensional shape.

The multilayer body 2 includes a first main surface 201 and a second main surface 202. The second electrode P2 is provided in a second dielectric layer (not illustrated) proximate to the second main surface 202 of the multilayer body 2. Additionally, the multiple first electrodes P1 are provided in a first dielectric layer (not illustrated) proximate to the first main surface 201 of the multilayer body 2. The multiple first electrodes P1 are indicated by chain double-dashed lines in FIGS. 1 and 2.

The multiple terminals 3 (a common terminal T40, a first terminal T41, a second terminal T42, and a ground terminal GND) are electrodes having a planar shape and are provided in the multilayer body 2. More specifically, the multiple terminals 3 are disposed on the second main surface 202 of the multilayer body 2. The multiple terminals 3 are, for example, LGA (land grid array) terminals that are regularly arranged on the second main surface 202 of the multilayer body 2. The multiple terminals 3 are external terminals to connect the diplexer 1 and external devices (not illustrated).

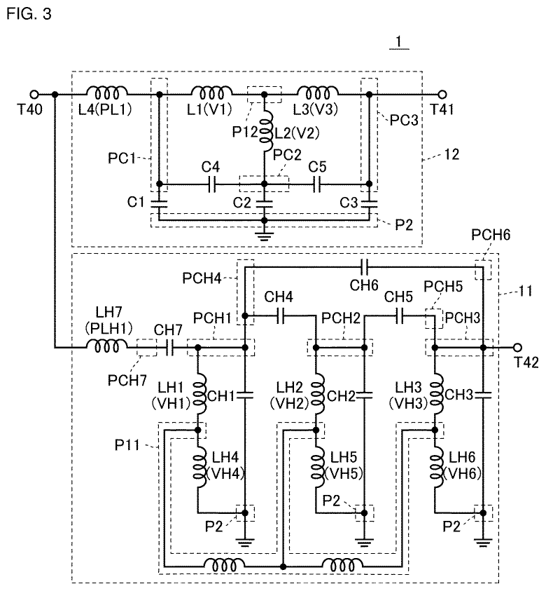

The multiple first electrodes P1 are provided in the first dielectric layer (not illustrated) among the multiple dielectric layers of the multilayer body 2. Each of the multiple first electrodes P1 is a planar electrode having a planar shape. When viewed in plan from the laminating direction (first direction D1) of the multilayer body 2, each of the first electrodes P1 has a rectangular or substantially rectangular shape. As in FIG. 3 described later, among the multiple first electrodes P1, a first electrode P11 is an electrode for the first filter 11, and a first electrode P12 is an electrode for the second filter 12.

The second electrode P2 is provided in the second dielectric layer (not illustrated) different from the first dielectric layer among the multiple dielectric layers of the multilayer body 2. The second electrode P2 is a planar electrode having a planar shape. The second electrode P2 is connected to the ground terminal GND. More specifically, the second electrode P2 is connected to the ground terminal GND, which is disposed on the second main surface 202 of the multilayer body 2, with a via (not illustrated) interposed therebetween.

From the above, the first filter 11 and the second filter 12 are connected to the common ground terminal GND with the second electrode P2 interposed therebetween.

The first filter 11 includes the multiple capacitor electrodes PCH0, as illustrated in FIGS. 1 and 2. The multiple capacitor electrodes PCH0 include a first capacitor electrode PCH1, a second capacitor electrode PCH2, a third capacitor electrode PCH3, a fourth capacitor electrode PCH4, a fifth capacitor electrode PCH5, a sixth capacitor electrode PCH6, and a seventh capacitor electrode PCH7.

The first capacitor electrode PCH1 has a planar shape and is provided in a dielectric layer (not illustrated) between the first electrode P11 and the second electrode P2 in the first direction D1. The first capacitor electrode PCH1 is spaced apart from the second electrode P2, and defines a first capacitor CH1 (see FIG. 3) between itself and the second electrode P2. The first capacitor electrode PCH1 is connected to a first inductor via VH1.

The second capacitor electrode PCH2 has a planar shape and is provided in a dielectric layer (not illustrated) between the first electrode P11 and the second electrode P2 in the first direction D1. The second capacitor electrode PCH2 is spaced apart from the second electrode P2, and defines a second capacitor CH2 (see FIG. 3) between itself and the second electrode P2. The second capacitor electrode PCH2 is connected to a second inductor via VH2.

The third capacitor electrode PCH3 has a planar shape and is provided in a dielectric layer (not illustrated) between the first electrode P11 and the second electrode P2 in the first direction D1. The third capacitor electrode PCH3 is spaced apart from the second electrode P2, and defines a third capacitor CH3 (see FIG. 3) between itself and the second electrode P2. The third capacitor electrode PCH3 is connected to the second terminal T42 with a via conductor VH31 interposed therebetween.

The fourth capacitor electrode PCH4 has a planar shape and is provided in a dielectric layer (not illustrated) between the first electrode P11 and the second electrode P2 in the first direction D1. The fourth capacitor electrode PCH4 is spaced apart from the second capacitor electrode PCH2, and defines a fourth capacitor CH4 (see FIG. 3) between itself and the second capacitor electrode PCH2.

The fifth capacitor electrode PCH5 has a planar shape and is provided in a dielectric layer (not illustrated) between the first electrode P11 and the second electrode P2 in the first direction D1. The fifth capacitor electrode PCH5 is spaced apart from the second capacitor electrode PCH2, and defines a fifth capacitor CH5 (see FIG. 3) between itself and the second capacitor electrode PCH2.

The sixth capacitor electrode PCH6 has a planar shape and is provided in a dielectric layer (not illustrated) between the first electrode P11 and the second electrode P2 in the first direction D1. The sixth capacitor electrode PCH6 is spaced apart from the fourth capacitor electrode PCH4, and defines a sixth capacitor CH6 (see FIG. 3) between itself and the fourth capacitor electrode PCH4.

The seventh capacitor electrode PCH7 has a planar shape and is provided in a dielectric layer (not illustrated) between the first electrode P11 and the second electrode P2 in the first direction D1. The seventh capacitor electrode PCH7 is spaced apart from the first capacitor electrode PCH1, and defines a seventh capacitor CH7 (see FIG. 3) between itself and the first capacitor electrode PCH1. The seventh capacitor electrode PCH7 is connected to a via conductor VH71.

Additionally, the first filter 11 includes, as illustrated in FIGS. 1 and 2, the multiple open vias Va described later, the multiple short-circuit vias Vb described later, and an inductor pattern portion PLH1. The multiple open vias Va include the first inductor via VH1, the second inductor via VH2, and the third inductor via VH3. The multiple short-circuit vias Vb include a fourth inductor via VH4, a fifth inductor via VH5, and a sixth inductor via VH6.

The first inductor via VH1 is connected between the first capacitor electrode PCH1 and the first electrode P11. The first inductor via VH1 defines a first inductor LH1 (see FIG. 3).

The second inductor via VH2 is connected between the second capacitor electrode PCH2 and the first electrode P11. The second inductor via VH2 defines a second inductor LH2 (see FIG. 3).

The third inductor via VH3 is connected between the third capacitor electrode PCH3 and the first electrode P11. The third inductor via VH3 defines a third inductor LH3 (see FIG. 3).

The fourth inductor via VH4 is connected between the first electrode P11 and the second electrode P2. The fourth inductor via VH4 defines a fourth inductor LH4 (see FIG. 3).

The fifth inductor via VH5 is connected between the first electrode P11 and the second electrode P2. The fifth inductor via VH5 defines a fifth inductor LH5 (see FIG. 3).

The sixth inductor via VH6 is connected between the first electrode P11 and the second electrode P2. The sixth inductor via VH6 defines a sixth inductor LH6 (see FIG. 3).

The inductor pattern portion PLH1 includes, as illustrated in FIGS. 1 and 2, a first end connected to the seventh capacitor electrode PCH7 and a second end connected to the common terminal T40. The inductor pattern portion PLH1 defines a seventh inductor LH7 (see FIG. 3).

More specifically, the inductor pattern portion PLH1 includes multiple (two in the illustrated example) pattern portions PLH11 and PLH12, and multiple (two in the illustrated example) via conductors VH71 and VH72. The pattern portion PLH11 is connected to the common terminal T40 with the via conductor V42 interposed therebetween. The pattern portion PLH12 is connected to the seventh capacitor electrode PCH7 with the via conductor VH71 interposed therebetween. Moreover, the pattern portion PLH11 and the pattern portion PLH12 are connected by the via conductor VH72 and arranged side by side in the first direction D1. The via conductor VH71 corresponds to a first end of the inductor pattern portion PLH1, and the via conductor V42 corresponds to a second end of the inductor pattern portion PLH1. The pattern portion PLH11 is provided in a state of being wound in a plane in one dielectric layer (not illustrated) among the multiple dielectric layers of the multilayer body 2. The pattern portion PLH12 is provided in a state of being wound in a plane in one dielectric layer (not illustrated) different from the dielectric layer where the pattern portion PLH11 is provided, among the multiple dielectric layers of the multilayer body 2.

The inductor pattern portion PLH1 defines a helical coil. The helical coil is a coil including one or more turns. More preferably, the helical coil is a coil including two or more turns. In the inductor pattern portion PLH1, the distance between the pattern portion PLH11 and the pattern portion PLH12, that is, the interlayer distance of the helical coil, is about 50 μm or more, for example.

As illustrated in FIGS. 1 and 2, in the first filter 11, the first to third inductor vias VH1 to VH3 are not directly connected to the second electrode P2, which is at the ground potential. The first inductor via VH1 is connected to the first capacitor electrode PCH1, the second inductor via VH2 is connected to the second capacitor electrode PCH2, and the third inductor via VH3 is connected to the third capacitor electrode PCH3. The first to third capacitor electrodes PCH1 to PCH3 face the second electrode P2. The first to third inductor vias VH1 to VH3, one ends of which are connected to the capacitor electrodes, are referred to as the open vias Va. The open vias Va may be vias including both ends connected to the capacitor electrodes. Meanwhile, the fourth to sixth inductor vias VH4 to VH6 are directly connected to the second electrode P2, which is at the ground potential. The fourth to sixth inductor vias VH4 to VH6, one ends of which are connected to the first electrode P1 and the other ends of which are connected to the second electrode P2, are referred to as the short-circuit vias Vb.

Then, as illustrated in FIG. 2, in the first filter 11, all of the first to third inductor vias VH1 to VH3, which are the open vias Va, are disposed at positions closer to a boundary surface F1 between the first filter 11 and the second filter 12 than all of the fourth to sixth inductor vias VH4 to VH6, which are the short-circuit vias Vb.

The second filter 12 includes the multiple capacitor electrodes PC0, as illustrated in FIGS. 1 and 2. The multiple capacitor electrodes PC0 include a first capacitor electrode PC1, a second capacitor electrode PC2, and a third capacitor electrode PC3.

The first capacitor electrode PC1 has a planar shape and is provided in a dielectric layer (not illustrated) between the first electrode P12 and the second electrode P2 in the first direction D1. The first capacitor electrode PC1 is spaced apart from the second electrode P2, and defines a first capacitor C1 (see FIG. 3) between itself and the second electrode P2. The first capacitor electrode PC1 is connected to a first inductor pattern portion PL1.

The second capacitor electrode PC2 has a planar shape and is provided in a dielectric layer (not illustrated) between the first electrode P12 and the second electrode P2 in the first direction D1. More specifically, the second capacitor electrode PC2 includes a first portion and a second portion. The second capacitor electrode PC2 is spaced apart from the second electrode P2, and defines a second capacitor C2 (see FIG. 3) between itself and the second electrode P2.

The third capacitor electrode PC3 has a planar shape and is provided in a dielectric layer (not illustrated) between the first electrode P12 and the second electrode P2 in the first direction D1. The third capacitor electrode PC3 is spaced apart from the second electrode P2, and defines a third capacitor C3 (see FIG. 3) between itself and the second electrode P2. The third capacitor electrode PC3 is connected to the first terminal T41 with a via (not illustrated) interposed therebetween.

The first capacitor electrode PC1 and the second capacitor electrode PC2 define a fourth capacitor C4 (see FIG. 3). The second capacitor electrode PC2 and the third capacitor electrode PC3 define a fifth capacitor C5 (see FIG. 3). More specifically, the first portion of the second capacitor electrode PC2 and the first capacitor electrode PC1 define the fourth capacitor C4. The second portion of the second capacitor electrode PC2 and the third capacitor electrode PC3 define the fifth capacitor C5.

That is, the first capacitor electrode PC1, the second capacitor electrode PC2, and the third capacitor electrode PC3 are provided between the first electrode P12 and the second electrode P2 in the laminating direction (first direction D1) of the multilayer body 2. Here, when viewed in plan from the laminating direction of the multilayer body 2, the first capacitor electrode PC1 may partially overlap the first electrode P12 and the second electrode P2, or the first capacitor electrode PC1 may entirely overlap the first electrode P12 and the second electrode P2. In other words, when viewed in plan from the laminating direction of the multilayer body 2, the first capacitor electrode PC1 is provided between the first electrode P12 and the second electrode P2 such that at least a portion of the first capacitor electrode PC1 overlaps the first electrode P12 and the second electrode P2. Additionally, when viewed in plan from the laminating direction of the multilayer body 2, the second capacitor electrode PC2 may partially overlap the first electrode P12 and the second electrode P2, or the second capacitor electrode PC2 may entirely overlap the first electrode P12 and the second electrode P2. In other words, when viewed in plan from the laminating direction of the multilayer body 2, the second capacitor electrode PC2 is provided between the first electrode P12 and the second electrode P2 such that at least a portion of the second capacitor electrode PC2 overlaps the first electrode P12 and the second electrode P2. Furthermore, when viewed in plan from the laminating direction of the multilayer body 2, the third capacitor electrode PC3 may partially overlap the first electrode P12 and the second electrode P2, or the third capacitor electrode PC3 may entirely overlap the first electrode P12 and the second electrode P2. In other words, when viewed in plan from the laminating direction of the multilayer body 2, the third capacitor electrode PC3 is provided between the first electrode P12 and the second electrode P2 such that at least a portion of the third capacitor electrode PC3 overlaps the first electrode P12 and the second electrode P2.

The second filter 12 includes the multiple vias V0 for the second filter and the first inductor pattern portion PL1, as illustrated in FIGS. 1 and 2. The multiple vias V0 for the second filter include a first inductor via V1, a second inductor via V2, and a third inductor via V3.

The first inductor via V1 is connected between the first capacitor electrode PC1 and the first electrode P12. The first inductor via V1 defines a first inductor L1 (see FIG. 3).

The second inductor via V2 is connected between the second capacitor electrode PC2 and the first electrode P12. The second inductor via V2 defines a second inductor L2 (see FIG. 3). The second inductor via V2 includes multiple (two in the illustrated example) via conductors V21 and V22 extending in the laminating direction (first direction D1) of the multilayer body 2. The multiple via conductors V21 and V22 are connected in parallel between the second capacitor electrode PC2 and the first electrode P12. Additionally, the multiple via conductors V21 and V22 are arranged side by side along a second direction D2.

The third inductor via V3 is connected between the third capacitor electrode PC3 and the first electrode P12. The third inductor via V3 defines a third inductor L3 (see FIG. 3). The third inductor via V3 includes multiple (two in the illustrated example) via conductors V31 and V32 extending in the laminating direction (first direction D1) of the multilayer body 2. The multiple via conductors V31 and V32 are connected in parallel between the third capacitor electrode PC3 and the first electrode P12. Additionally, the multiple via conductors V31 and V32 are arranged side by side along the second direction D2.

The first inductor pattern portion PL1 includes a first end connected to the first capacitor electrode PC1, and a second end connected to the common terminal T40, as illustrated in FIGS. 1 and 2. The first inductor pattern portion PL1 defines a fourth inductor L4 (see FIG. 3).

More specifically, the first inductor pattern portion PL1 includes multiple (two in the illustrated example) pattern portions P41 and P42 and multiple (three in the illustrated example) via conductors V41 to V43. The pattern portion P42 is connected to the first capacitor electrode PC1 with the via conductor V41 interposed therebetween. The pattern portion P41 is connected to the common terminal T40 with the via conductor V42 interposed therebetween. Moreover, the pattern portion P41 and the pattern portion P42 are connected by the via conductor V43 and arranged side by side in the first direction D1. The via conductor V41 corresponds to a first end of the first inductor pattern portion PL1, and the via conductor V42 corresponds to a second end of the first inductor pattern portion PL1. The pattern portion P41 is provided in a state of being wound in a plane in one dielectric layer (not illustrated) among the multiple dielectric layers of the multilayer body 2. The pattern portion P42 is provided in a state of being wound in a plane in one dielectric layer (not illustrated) different from the dielectric layer where the pattern portion P41 is provided, among the multiple dielectric layers of the multilayer body 2.

The first inductor pattern portion PL1 defines a helical coil. The helical coil is a coil including one or more turns. More preferably, the helical coil is a coil including two or more turns. In the first inductor pattern portion PL1, the distance between the pattern portion P41 and the pattern portion P42, that is, the interlayer distance of the helical coil, is about 50 μm or more, for example.

The circuit configuration of the diplexer 1 according to the present example embodiment will be described. FIG. 3 is a schematic diagram of the diplexer 1 according to the present example embodiment. The diplexer 1 includes the common terminal T40, the first terminal T41, the second terminal T42, the first filter 11, and the second filter 12.

The first filter 11 is connected between the common terminal T40 and the second terminal T42. The first filter 11 is a high-pass filter (HPF) that passes signals in a passband higher than a predetermined frequency.

The first filter 11 includes the first capacitor CH1, the second capacitor CH2, the third capacitor CH3, the fourth capacitor CH4, the fifth capacitor CH5, and the sixth capacitor CH6. The first filter 11 also includes the first inductor LH1, the second inductor LH2, the third inductor LH3, the fourth inductor LH4, the fifth inductor LH5, and the sixth inductor LH6. The first filter 11 further includes the seventh inductor LH7 and the seventh capacitor CH7.

The first capacitor CH1 is provided between the first capacitor electrode PCH1 and the second electrode P2. The first capacitor CH1 includes the first capacitor electrode PCH1, the second electrode P2, and a dielectric layer disposed therebetween. The first inductor LH1 is connected between the first capacitor electrode PCH1 and the first electrode P12. The first inductor LH1 corresponds to the first inductor via VH1. The fourth inductor LH4 is connected between the first electrode P12 and the second electrode P2. The fourth inductor LH4 corresponds to the fourth inductor via VH4.

The second capacitor CH2 is provided between the second capacitor electrode PCH2 and the second electrode P2. The second capacitor CH2 includes the second capacitor electrode PCH2, the second electrode P2, and a dielectric layer disposed therebetween. The second inductor LH2 is connected between the second capacitor electrode PCH2 and the first electrode P12. The second inductor LH2 corresponds to the second inductor via VH2. The fifth inductor LH5 is connected between the first electrode P12 and the second electrode P2. The fifth inductor LH5 corresponds to the fifth inductor via VH5.

The third capacitor CH3 is provided between the third capacitor electrode PCH3 and the second electrode P2. The third capacitor CH3 includes the third capacitor electrode PCH3, the second electrode P2, and a dielectric layer disposed therebetween. The third capacitor CH3 is connected to the second terminal T42. The third inductor LH3 is connected between the third capacitor electrode PCH3 and the first electrode P12. The third inductor LH3 corresponds to the third inductor via VH3. The sixth inductor LH6 is connected between the first electrode P12 and the second electrode P2. The sixth inductor LH6 corresponds to the sixth inductor via VH6.

The fourth capacitor CH4 is provided between the second capacitor electrode PCH2 and the fourth capacitor electrode PCH4. The fourth capacitor CH4 includes the second capacitor electrode PCH2, the fourth capacitor electrode PCH4, and a dielectric layer disposed therebetween.

The fifth capacitor CH5 is provided between the second capacitor electrode PCH2 and the fifth capacitor electrode PCH5. The fifth capacitor CH5 includes the second capacitor electrode PCH2, the fifth capacitor electrode PCH5, and a dielectric layer disposed therebetween.

The sixth capacitor CH6 is provided between the fourth capacitor electrode PCH4 and the sixth capacitor electrode PCH6. The sixth capacitor CH6 includes the fourth capacitor electrode PCH4, the sixth capacitor electrode PCH6, and a dielectric layer disposed therebetween.

The seventh inductor LH7 is connected between the common terminal T40 and the seventh capacitor CH7. The seventh inductor LH7 corresponds to the inductor pattern portion PLH1.

The seventh capacitor CH7 is connected between the seventh capacitor electrode PCH7 and the first capacitor electrode PCH1. The seventh capacitor CH7 includes the seventh capacitor electrode PCH7, the first capacitor electrode PCH1, and a dielectric layer disposed therebetween. The seventh capacitor CH7 is connected in series with the seventh inductor LH7.

The second filter 12 is connected between the common terminal T40 and the first terminal T41. The second filter 12 is a low-pass filter (LPF) that passes signals in a frequency band lower than a predetermined frequency.

The second filter 12 includes the first capacitor C1 (a first capacitor for the second filter), the second capacitor C2 (a second capacitor for the second filter), the third capacitor C3 (a third capacitor for the second filter), the fourth capacitor C4, the fifth capacitor C5, the first inductor L1 (a first inductor for the second filter), the second inductor L2 (a second inductor for the second filter), the third inductor L3 (a third inductor for the second filter), and the fourth inductor L4.

The first capacitor C1 is provided between the first capacitor electrode PC1 and the second electrode P2. The first capacitor C1 includes the first capacitor electrode PC1, the second electrode P2, and a dielectric layer disposed therebetween. The second electrode P2 is connected to the ground terminal GND. The first inductor L1 is connected between the first capacitor electrode PC1 and the first electrode P1. The first inductor L1 corresponds to the first inductor via V1.

The second capacitor C2 is provided between the second capacitor electrode PC2 and the second electrode P2. The second capacitor C2 includes the second capacitor electrode PC2, the second electrode P2, and a dielectric layer disposed therebetween. The second inductor L2 is connected between the second capacitor electrode PC2 and the first electrode P1. The second inductor L2 corresponds to the second inductor via V2 (via conductors V21 and V22).

The third capacitor C3 is provided between the third capacitor electrode PC3 and the second electrode P2. The third capacitor C3 includes the third capacitor electrode PC3, the second electrode P2, and a dielectric layer disposed therebetween. The third capacitor C3 is connected to the first terminal T41. The third inductor L3 is connected between the third capacitor electrode PC3 and the first electrode P1. The third inductor L3 corresponds to the third inductor via V3 (via conductors V31 and V32).

The fourth capacitor C4 is provided between the first capacitor electrode PC1 and the second capacitor electrode PC2. The fourth capacitor C4 includes the first capacitor electrode PC1, the second capacitor electrode PC2, and a dielectric layer disposed therebetween.

The fifth capacitor C5 is provided between the second capacitor electrode PC2 and the third capacitor electrode PC3. The fifth capacitor C5 includes the second capacitor electrode PC2, the third capacitor electrode PC3, and a dielectric layer disposed therebetween.

The fourth inductor L4 is connected between the common terminal T40 and the first capacitor electrode PC1. The fourth inductor L4 corresponds to the first inductor pattern portion PL1.

A diplexer as described above is designed to have predetermined pass characteristics. Specifically, each capacitance and each inductance are designed such that the high-pass filter passes signals in a frequency band higher than a predetermined frequency, and the low-pass filter passes signals in a frequency band lower than a predetermined frequency. In the multilayer body 2, the via conductors or capacitor electrodes that define the high-pass filter may have parasitic components with other via conductors or circuit electrodes when these other via conductors or circuit electrodes are proximately disposed thereto. In such a case, insertion loss may occur on the high-frequency side of the passband of the high-pass filter.

Such a diplexer may be installed in an electronic device, such as a mobile terminal, for example. In that case, it is preferable that the substrate on which the diplexer is mounted is disposed closer to surrounding components for miniaturization or higher-density integration of the electronic device. At this time, the substrate on which the diplexer is mounted may be shielded by a metal shield (hereinafter also referred to as a “shield ”) to block electromagnetic waves from surrounding components. However, in this case, because the diplexer is proximate to the shield, the diplexer may be affected electromagnetically by the shield, such as parasitic components as described above may be generated, resulting in variations in its pass characteristics. When the shield is proximate to a diplexer 1a according to a comparative configuration described below, its pass characteristics vary.

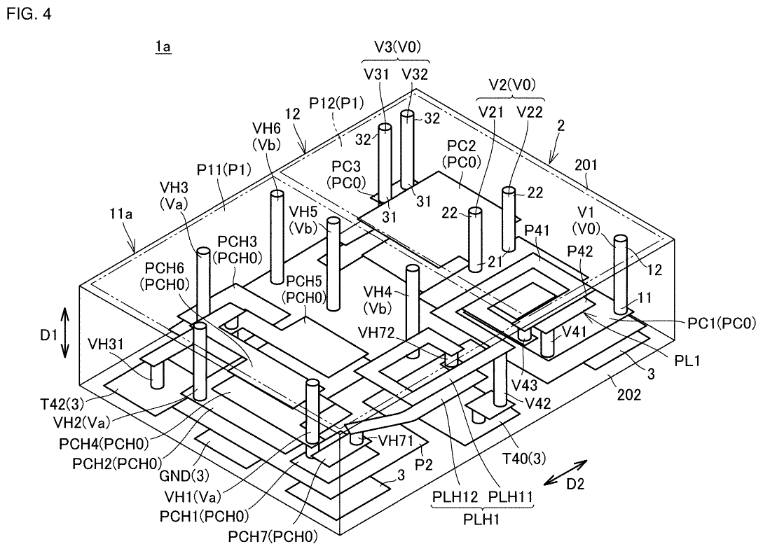

First, the structure of the diplexer 1a according to the comparative configuration will be described. FIG. 4 is a perspective view of the diplexer 1a according to the comparative configuration. The diplexer 1a includes a first filter 11a and a second filter 12. Similar to the first filter 11 according to the present example embodiment, the first filter 11a includes the first to third inductor vias VH1 to VH3, which are open vias Va, and the fourth to sixth inductor vias VH4 to VH6, which are short-circuit vias Vb.

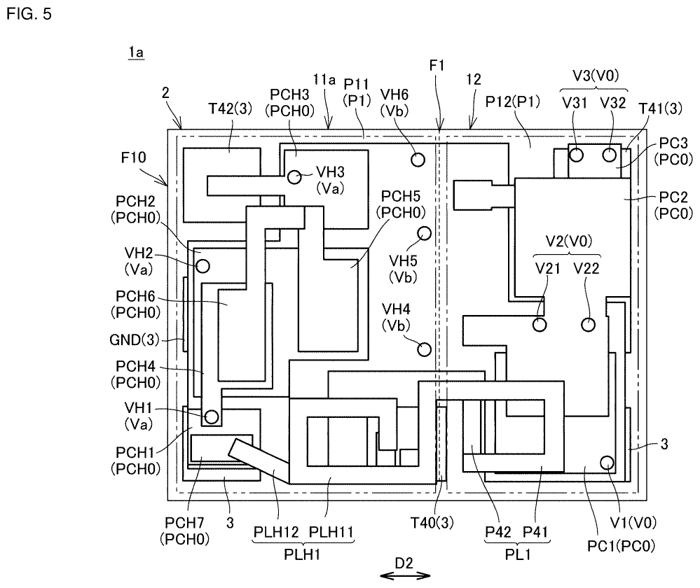

FIG. 5 is a plan view of the diplexer 1a according to the comparative configuration. In the first filter 11a, all of the fourth to sixth inductor vias VH4 to VH6, which are the short-circuit vias Vb, are disposed at positions closer to the boundary surface F1 between the first filter 11a and the second filter 12 than all of the first to third inductor vias VH1 to VH3, which are the open vias Va. In other words, all of the multiple open vias Va are disposed at positions closer to a side surface F10 facing the boundary surface F1, among the side surfaces of the diplexer 1a, than all of the multiple short-circuit vias Vb.

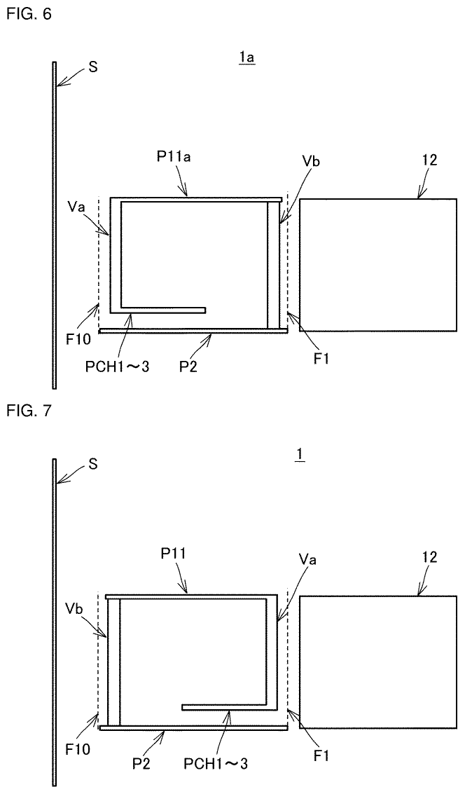

Next, a case in which a shield S is disposed proximate to the diplexer 1a according to the comparative configuration will be described. FIG. 6 is a schematic diagram of the side surface of the diplexer 1a according to the comparative configuration. In the diplexer 1a, as described above, all of the multiple open vias Va are disposed at positions closer to the side surface F10 than all of the multiple short-circuit vias Vb. Additionally, the open vias Va are not directly connected to the second electrode P2, which is at the ground potential, but instead are connected to the first to third capacitor electrodes PCH1 to PCH3. Therefore, when the shield S is brought into close proximity to the side surface F10, the open vias Va and the first to third capacitor electrodes PCH1 to PCH3 are brought into close proximity to the shield S.

Here, since the shield S blocks electromagnetic waves from surrounding components, the shield S is connected to the ground of the substrate where the diplexer 1a is mounted. Therefore, the shield S has the same potential as the second electrode P2, which is at the ground potential of the diplexer 1a. Meanwhile, each of the first to third capacitor electrodes PCH1 to PCH3 defines a capacitor between itself and the second electrode P2, which is at the ground potential, as described above. Therefore, the open vias Va and the first to third capacitor electrodes PCH1 to PCH3 have a potential difference between themselves and the second electrode P2. That is, they have a potential difference between themselves and the shield S. Then, since the open vias Va and the first to third capacitor electrodes PCH1 to PCH3 have a potential difference between themselves and the shield S, parasitic capacitance is generated between them and the shield S. This parasitic capacitance equivalently defines a capacitance with respect to the ground potential, and because this capacitance is added to the filter circuit illustrated in FIG. 3, the diplexer 1a according to the comparative configuration exhibits variations in its pass characteristics.

Next, a case in which the shield S is disposed proximate to the diplexer 1 according to the present example embodiment will be described. FIG. 7 is a schematic diagram of the side surface of the diplexer 1 according to the present example embodiment. In the diplexer 1 according to the present example embodiment, all of the multiple open vias Va are disposed at positions closer to the boundary surface F1 than all of the multiple short-circuit vias Vb, as described above. Thus, when the shield S is brought into close proximity to the side surface F10, all of the multiple open vias Va are not brought into close proximity to the shield S. Therefore, no parasitic capacitance is generated between the open vias Va and the first to third capacitor electrodes PCH1 to PCH3, and the shield S.

Meanwhile, in the diplexer 1 according to the present example embodiment, all of the multiple short-circuit vias Vb are disposed proximate to the shield S. As described above, the short-circuit vias Vb are directly connected to the second electrode P2, which is at the ground potential. Thus, there is substantially no potential difference between the short-circuit vias Vb and the shield S. Therefore, no parasitic capacitance is generated between the short-circuit vias Vb and the shield S. As such, in the diplexer 1 according to the present example embodiment, since no parasitic capacitance is generated in any of the open vias Va, the first to third capacitor electrodes PCH1 to PCH3, and the short-circuit vias Vb, it is possible to reduce or prevent variations in the pass characteristics due to electromagnetic influence from the proximate metal component.

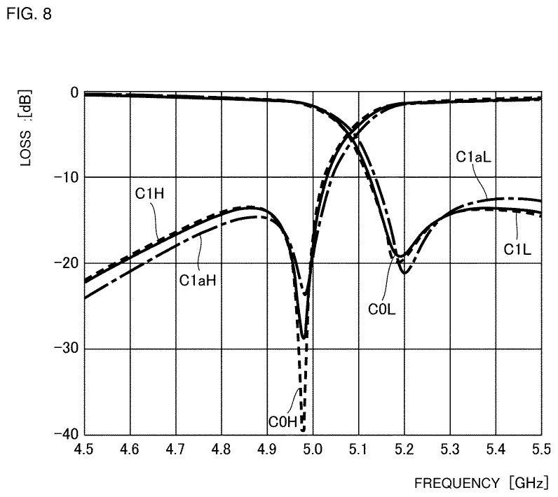

Now, how the pass characteristics of the diplexer 1a of the comparative configuration and the diplexer 1 of the present example embodiment vary when the shield S is brought into close proximity thereto will be described. FIG. 8 is a diagram illustrating an example of variations in the pass characteristics of each diplexer. In FIG. 8, the horizontal axis represents frequency [GHz], and the vertical axis represents loss [dB]. The pass characteristics of the first filter 11a and the second filter 12 according to the comparative configuration when the shield S is brought into close proximity are indicated by pass characteristics C1aH and C1aL, respectively (both indicated by one-dot chain lines). Additionally, the pass characteristics of the first filter 11 and the second filter 12 according to the present example embodiment when the shield S is brought into close proximity are indicated by pass characteristics C1H and C1L, respectively (both indicated by solid lines). When the shield S is not brought into close proximity, the pass characteristics of the first filter 11a according to the comparative configuration and the first filter 11 according to the present example embodiment are both indicated by a pass characteristic C0H (broken line), and the pass characteristics of the second filter 12 according to the comparative configuration and the second filter 12 according to the present example embodiment are both indicated by a pass characteristic C0L (broken line). Here, the pass characteristics of the first filter 11a according to the comparative configuration and the pass characteristics of the first filter 11 according to the present example embodiment are the same or substantially the same because the only difference between the first filter 11a according to the comparative configuration and the first filter 11 according to the present example embodiment lies in the positions where the open vias Va and the short-circuit vias Vb are disposed.

As illustrated in FIG. 8, in the diplexer 1a according to the comparative configuration, because the shield S is brought into close proximity, the pass characteristic C1aH of the first filter 11a exhibits a higher passband. Meanwhile, in the diplexer 1 according to the present example embodiment, even when the shield S is brought into close proximity, the pass characteristic C1H of the first filter 11 exhibits only small variations in the passband, as compared with the pass characteristic C1aH according to the comparative configuration. The pass characteristic C1L of the second filter 12 according to the present example embodiment exhibits smaller variations than the pass characteristic C1aL of the second filter 12 according to the comparative configuration.

As such, in the diplexer 1 according to the present example embodiment, even when the shield S is brought into close proximity, no parasitic capacitance is generated, unlike in the diplexer 1a of the comparative configuration. That is, the diplexer 1 according to the present example embodiment is able to reduce or prevent variations in its pass characteristics due to electromagnetic influence from the proximate metal shield.

Furthermore, in the diplexer 1 according to the present example embodiment, as illustrated in FIGS. 1 and 2, all of the fourth to sixth capacitor electrodes PCH4 to PCH6 of the first filter 11 are disposed at positions far from the second filter. Specifically, all of the fourth to sixth capacitor electrodes PCH4 to PCH6 are disposed at positions farther from the second filter than the second inductor via VH2 disposed at a position closest to the boundary surface F1 among the multiple open vias Va.

Here, when the fourth to sixth capacitor electrodes PCH4 to PCH6 of the first filter 11 are disposed at positions proximate to the second filter, there is a possibility that parasitic capacitance will be generated between the fourth to sixth capacitor electrodes PCH4 to PCH6 and the capacitor electrodes (first to third capacitor electrodes PC1 to PC3) of the second filter. This may undesirably reduce the isolation between the first filter 11 and the second filter 12.

Accordingly, in the diplexer 1 according to the present example embodiment, since all of the fourth to sixth capacitor electrodes PCH4 to PCH6 of the first filter 11 are disposed at positions far from the second filter, it is possible to improve the isolation between the first filter 11 and the second filter 12.

In the diplexer 1 according to the present example embodiment, it has been described that, in the first filter 11, all of the multiple open vias Va are disposed at positions closer to the boundary surface F1 than all of the short-circuit vias Vb; however, the present example embodiment is not limited thereto.

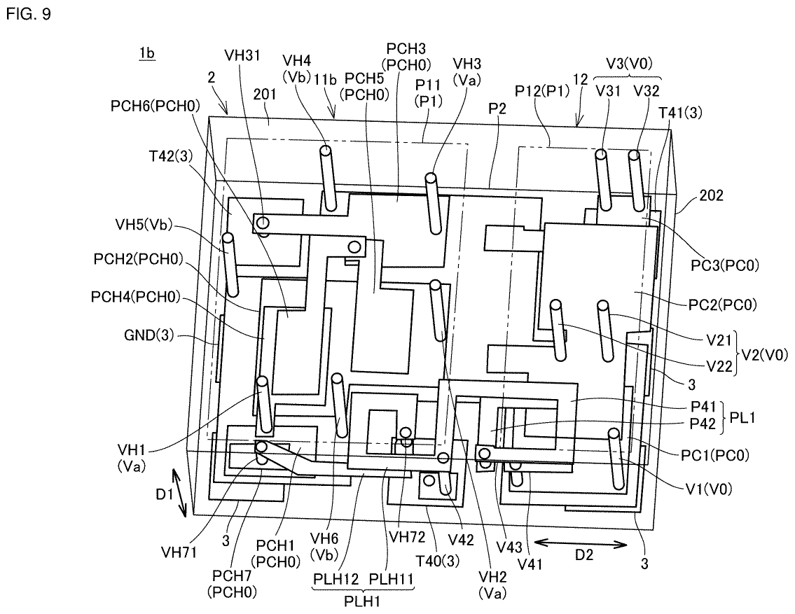

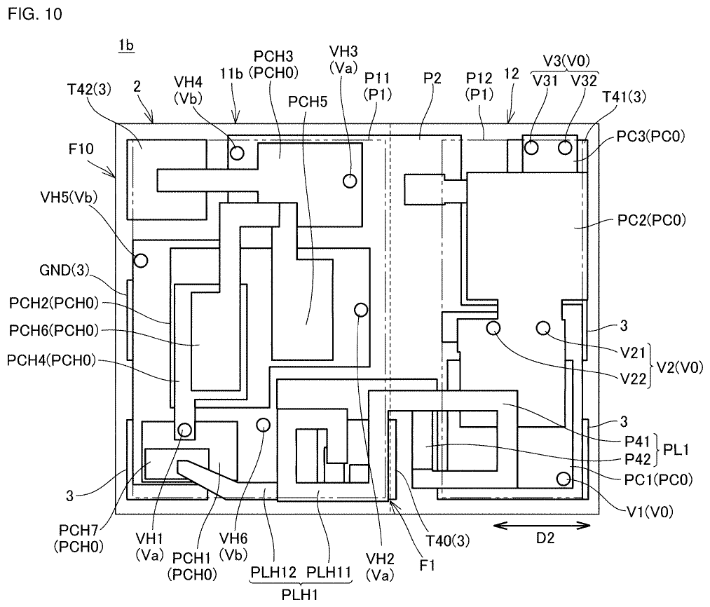

FIG. 9 is a perspective view of a diplexer 1b according to Modified example 1 of an example embodiment of the present invention. FIG. 10 is a plan view of the diplexer 1b according to Modified example 1. The diplexer 1b according to Modified example 1 includes a first filter 11b and the second filter 12. In the first filter 11b, unlike the first filter 11 according to the present example embodiment, only the first inductor via VH1 and the second inductor via VH2 among the multiple open vias Va are disposed at positions closer to the boundary surface F1 than all of the multiple short-circuit vias Vb.

As in the first filter 11b according to Modified example 1, a majority of the multiple open vias Va may be disposed at positions closer to the boundary surface F1 than all of the multiple short-circuit vias Vb. In doing so, the degree of freedom in disposing the open vias Va and the short-circuit vias Vb is improved, thus facilitating the design of the internal structure of the first filter 11b. In the diplexer 1b according to Modified example 1, no parasitic capacitance is generated between the majority of the open vias Va and the shield S, and therefore it is possible to reduce or prevent variations in the pass characteristics due to electromagnetic influence from the proximate metal shield.

Furthermore, according to Modified example 2 of an example embodiment of the present invention, a majority of the multiple open vias Va may be disposed at positions closer to the boundary surface F1 than at least one of the multiple short-circuit vias Vb. In doing so, as compared with Modified example 1, the degree of freedom in disposing the open vias Va and the short-circuit vias Vb is further improved, thus facilitating the design of the internal structure of the first filter.

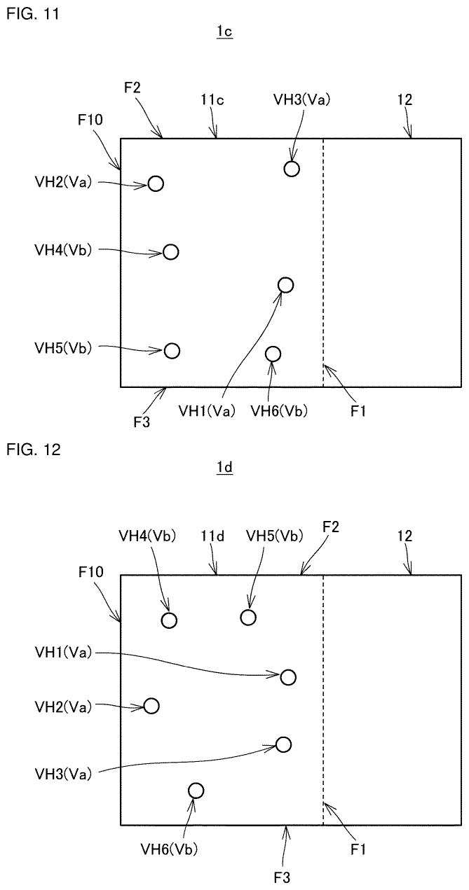

FIG. 11 is a plan view of a diplexer 1c according to Modified example 3 of an example embodiment of the present invention. Among the multiple side surfaces connecting the first main surface 201 and the second main surface 202 of the diplexer 1c, the two side surfaces located perpendicular or substantially perpendicular to the boundary surface F1 are referred to as a side surface F2 and a side surface F3. In a first filter 11c, the first inductor via VH1 and the third inductor via VH3 among the multiple open vias Va are disposed at positions closer to the boundary surface F1 than all of the multiple short-circuit vias Vb. In addition to that, in the first filter 11c, the second inductor via VH2 and the third inductor via VH3 among the multiple open vias Va are disposed at positions closer to the side surface F2 than all of the multiple short-circuit vias Vb.

As in the first filter 11c according to Modified example 3, a majority of the multiple open vias Va may further be disposed at positions closer to one of the two side surfaces (the side surface F2 in the present modified example) perpendicular or substantially perpendicular to the boundary surface F1 than all of the multiple short-circuit vias Vb.

In doing so, in the diplexer 1c according to Modified example 3, even when the shield S is brought into close proximity to either the side surface F10 or the side surface F3, a majority of the multiple open vias Va do not generate parasitic capacitance between themselves and the shield S. As a result, the diplexer 1c according to Modified example 3 is able to reduce or prevent variations in its pass characteristics due to electromagnetic influence from the proximate metal shield at the two side surfaces among the side surfaces of the diplexer 1c.

In the diplexer 1c according to Modified example 3, a majority of the multiple open vias Va are disposed at positions closer to either of the two side surfaces perpendicular or substantially perpendicular to the boundary surface F1 than all of the multiple short-circuit vias Vb. However, the present example embodiment is not limited thereto. According to Modified example 4 of an example embodiment of the present invention, it is only necessary that at least one of the multiple open vias Va is disposed at a position closer to the side surface F2 than at least one of the multiple short-circuit vias Vb. In doing so, as compared with the diplexer 1c according to Modified example 3, the degree of freedom in disposing the open vias Va and the short-circuit vias Vb is improved, thus facilitating the design of the internal structure of the first filter. In this case, even when the shield S is brought into close proximity to either the side surface F10 or the side surface F3, at least one of the multiple open vias Va does not form parasitic capacitance between itself and the shield S. Thus, even in Modified example 4 of an example embodiment of the present invention, it is possible to reduce or prevent variations in the pass characteristics due to electromagnetic influence from the proximate metal shield at the two side surfaces among the side surfaces of the diplexer.

FIG. 12 is a plan view of a diplexer 1d according to Modified example 5 of an example embodiment of the present invention. In a first filter 11d, the first inductor via VH1 and the third inductor via VH3 among the multiple open vias Va are disposed at positions closer to the boundary surface F1 than all of the multiple short-circuit vias Vb. In addition to that, in the first filter 11d, all of the multiple open vias Va are disposed at respective positions midway between the side surface F2 and the side surface F3 with respect to all of the short-circuit vias Vb.

Then, in the diplexer 1d according to Modified example 5, even when the shield S is brought into close proximity to any of the side surface F10, the side surface F2, or the side surface F3 of the diplexer 1d, all of the multiple open vias Va do not generate parasitic capacitance between themselves and the shield S. As a result, the diplexer 1d according to Modified example 5 is able to reduce or prevent variations in its pass characteristics due to electromagnetic influence from the proximate metal shield at the three side surfaces among the side surfaces of the diplexer 1c.

In the diplexer 1c according to Modified example 5, all of the multiple open vias Va are disposed at respective positions midway between the side surface F2 and the side surface F3 with respect to all of the multiple short-circuit vias Vb. However, the present example embodiment is not limited thereto. According to Modified example 6 of an example embodiment of the present invention, it is only necessary that at least one of the multiple open vias Va be disposed at a position midway between the side surface F2 and the side surface F3 with respect to all of the multiple short-circuit vias Vb. In doing so, as compared with the diplexer 1d according to Modified example 5, the degree of freedom in disposing the open vias Va and the short-circuit vias Vb is improved, thus facilitating the design of the internal structure of the first filter. Accordingly, even when the shield S is brought into close proximity to any of the side surface F10, the side surface F2, or the side surface F3, at least one of the multiple open vias Va does not generate parasitic capacitance between itself and the shield S. Thus, even in Modified example 6, it is possible to reduce or prevent variations in the pass characteristics due to electromagnetic influence from the proximate metal shield at the three side surfaces among the side surfaces of the diplexer.

In the diplexer 1 according to the above-described example embodiment, the first filter 11 and the second filter 12 are connected to the common ground terminal GND with the second electrode P2 interposed therebetween. However, example embodiments of the present invention are not limited to this configuration.

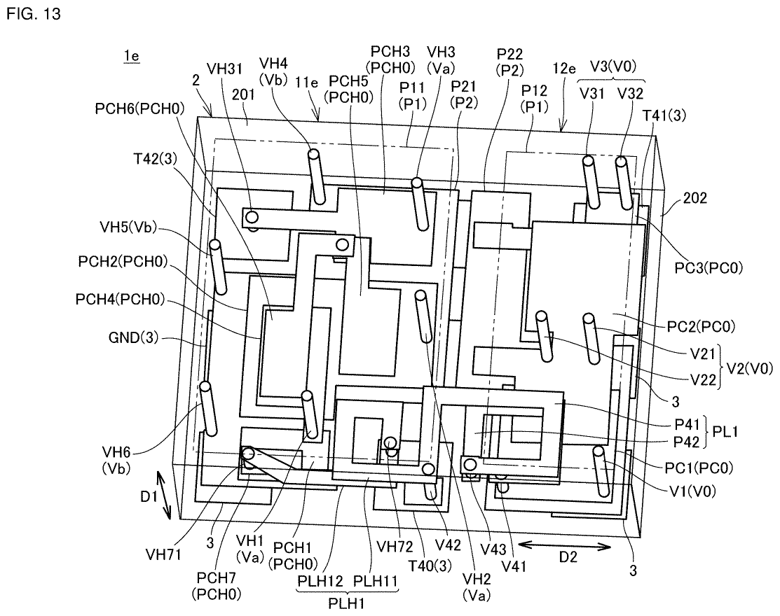

FIG. 13 is a perspective view of a diplexer 1e according to Modified example 7 of an example embodiment of the present invention. In the diplexer 1e, a first filter 11e includes a second electrode P21 that is provided in the second dielectric layer and that is connected to the ground terminal GND. Additionally, a second filter 12e includes a second electrode P22 (a second electrode for the second filter) that is provided in the second dielectric layer, that is connected to the ground terminal GND, and that is physically separated from the second electrode P21.

As in the diplexer 1e according to Modified example 7, the second electrode of the first filter and the second electrode of the second filter may be provided in the same dielectric layer but physically separated from each other. In doing so, as compared with a case in which the first filter and the second filter are connected to the common ground terminal GND, it is possible to improve the isolation between the first filter and the second filter. Furthermore, as compared with a case in which the second electrode of the first filter and the second electrode of the second filter are provided in different dielectric layers so that they are physically separated from each other, it is possible to reduce the number of dielectric layers.

In the diplexer 1 according to the above-described example embodiment, in the second filter 12, a majority of the first to third inductor vias V1 to V3 may be disposed at positions proximate to the boundary surface F1. A position proximate to the boundary surface F1 is a position where the distance from the boundary surface F1 is shorter than the distance from the side surface on the second filter 12 side of the two side surfaces facing the boundary surface F1.

Here, none of the first to third inductor vias V1 to V3 is directly connected to the second electrode P2, which is at the ground potential. Thus, when the shield S is brought into close proximity, the first to third inductor vias V1 to V3 generate parasitic capacitance between themselves and the shield S.

In that case, in a diplexer according to Modified example 8 of an example embodiment of the present invention, since a majority of the first to third inductor vias V1 to V3 are disposed at positions proximate to the boundary surface F1, they are not proximate to the shield S and thus do not generate parasitic capacitance between themselves and the shield S. Therefore, the diplexer according to Modified example 8 is able to reduce or prevent variations in its pass characteristics due to electromagnetic influence from the proximate metal member on either of the two side surfaces facing the boundary surface F1.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A diplexer comprising:
a plurality of dielectric layers that are laminated;
a first filter defining a high-pass filter; and
a second filter defining a low-pass filter adjacent to the first filter to pass signals in a frequency band lower than a passband of the first filter; wherein
the first filter includes:
a first electrode in a first dielectric layer among the plurality of dielectric layers;
a second electrode defining a ground electrode in a second dielectric layer different from the first dielectric layer among the plurality of dielectric layers;
a plurality of capacitor electrodes between the first electrode and the second electrode;
a plurality of open vias respectively connecting the first electrode and the plurality of capacitor electrodes; and
a plurality of short-circuit vias connecting the first electrode and the second electrode; and
at least one of the plurality of open vias is located at a position closer to a boundary surface between the first filter and the second filter than at least one of the plurality of short-circuit vias.

2. The diplexer according to claim 1, wherein a majority of the plurality of open vias are located at positions closer to the boundary surface than at least one of the plurality of short-circuit vias.

3. The diplexer according to claim 1, wherein a majority of the plurality of open vias are located at positions closer to the boundary surface than all of the plurality of short-circuit vias.

4. The diplexer according to claim 1, wherein all of the plurality of open vias are located at positions closer to the boundary surface than all of the plurality of short-circuit vias.

5. The diplexer according to claim 1, wherein
the diplexer has a rectangular or substantially parallel parallelepiped shape and includes a pair of main surfaces that are parallel or substantially parallel to the first dielectric layer and face each other, and a plurality of side surfaces connecting the main surfaces; and
at least one of the plurality of open vias is proximate to either of two of the plurality of side surfaces perpendicular or substantially perpendicular to the boundary surface among the plurality of side surfaces.

6. The diplexer according to claim 1, wherein
the diplexer has a rectangular or substantially rectangular parallelepiped shape and includes a pair of main surfaces parallel or substantially parallel to the first dielectric layer and face each other, and a plurality of side surfaces connecting the main surfaces; and
at least one of the plurality of open vias is located midway between two of the plurality of side surfaces perpendicular or substantially perpendicular to the boundary surface among the plurality of side surfaces.

7. The diplexer according to claim 1, wherein
in the first filter, the plurality of capacitor electrodes include:
a first capacitor electrode defining a first capacitor between itself and the second electrode;
a second capacitor electrode defining a second capacitor between itself and the second electrode; and
a third capacitor electrode defining a third capacitor between itself and the second electrode;
the plurality of open vias include:
a first inductor via connecting the first electrode and the first capacitor electrode, and defining a first inductor;
a second inductor via connecting the first electrode and the second capacitor electrode, and defining a second inductor; and
a third inductor via connecting the first electrode and the third capacitor electrode, and defining a third inductor; and
the plurality of short-circuit vias include:
a fourth inductor via connecting the first electrode and the second electrode, and defining a fourth inductor connected in series with the first inductor;
a fifth inductor via connecting the first electrode and the second electrode, and defining a fifth inductor connected in series with the second inductor; and
a sixth inductor via connecting the first electrode and the second electrode, and defining a sixth inductor connected in series with the third inductor.

8. The diplexer according to claim 7, wherein
the plurality of capacitor electrodes further include:
a fourth capacitor electrode defining a fourth capacitor between itself and the second capacitor electrode;
a fifth capacitor electrode defining a fifth capacitor between itself and the second capacitor electrode; and
a sixth capacitor electrode defining a sixth capacitor between itself and the fourth capacitor electrode; and
the fourth capacitor electrode, the fifth capacitor electrode, and the sixth capacitor electrode are all located at positions farther from the boundary surface than a via located at a position closest to the boundary surface among the first inductor via, the second inductor via, and the third inductor via.

9. The diplexer according to claim 7, wherein
the second filter includes:
a first electrode of the second filter in the first dielectric layer;
a second electrode of the second filter defining a ground electrode in the second dielectric layer;
a first capacitor electrode of the second filter between the first electrode of the second filter and the second electrode of the second filter, and defining a first capacitor of the second filter between itself and the second electrode of the second filter;
a second capacitor electrode of the second filter between the first electrode of the second filter and the second electrode of the second filter, and defining a second capacitor of the second filter between itself and the second electrode of the second filter;
a third capacitor electrode of the second filter between the first electrode of the second filter and the second electrode of the second filter, and defining a third capacitor of the second filter between itself and the second electrode of the second filter;
a first inductor via of the second filter connecting the first capacitor electrode of the second filter and the first electrode of the second filter, and defining a first inductor of the second filter;
a second inductor via of the second filter connecting the second capacitor electrode of the second filter and the first electrode of the second filter, and defining a second inductor of the second filter;
a third inductor via of the second filter connecting the third capacitor electrode of the second filter and the first electrode of the second filter, and defining a third inductor of the second filter; and
an inductor pattern portion of the second filter, connected to the first capacitor of the second filter, and defining a fourth inductor of the second filter.

10. The diplexer according to claim 9, wherein the second electrode and the second electrode of the second filter are spaced apart from each other.

11. The diplexer according to claim 9, wherein a majority of the first to third inductor vias of the second filter are located at positions closer to the boundary surface than a side surface on the second filter side among two side surfaces facing the boundary surface of the diplexer.

12. The diplexer according to claim 1, wherein
the diplexer has a rectangular or substantially rectangular parallelepiped shape and includes a pair of main surfaces parallel or substantially parallel to the first dielectric layer and face each other, and a plurality of side surfaces connecting the main surfaces; and
at least one of the plurality of short-circuit vias is located at a position closer to a side surface, among the plurality of side surfaces, proximate to a shield that shields the diplexer than at least one of the plurality of open vias.

13. The diplexer according to claim 1, wherein each of the plurality of dielectric layers includes a ceramic material.

14. The diplexer according to claim 1, wherein each of the plurality of capacitor electrodes has a planar shape.

15. The diplexer according to claim 7, wherein each of the first, second, third, fourth, fifth, and sixth inductors has a helical coil shape.

16. The diplexer according to claim 15, wherein the helical coil shape includes one or more turns.

17. The diplexer according to claim 15, wherein the helical coil shape includes two or more turns.
